(19) United States
(12) Patent Application Publication
(10) Pub. No.: US 2013/0056052 A1
(43) Pub. Date: Mar. 7, 2013

(54) THIN FILM SOLAR CELL

(71) Applicants: Jinhee Park, Seoul (KR); Soohyun Kim, Seoul (KR); Sehwon Ahn, Seoul (KR); Hongcheol Lee, Seoul (KR)

(72) Inventors: Jinhee Park, Seoul (KR); Soohyun Kim, Seoul (KR); Sehwon Ahn, Seoul (KR); Hongcheol Lee, Seoul (KR)

(21) Appl. No.: 13/564,298

(22) Filed: Aug. 1, 2012

(30) Foreign Application Priority Data
Sep. 6, 2011 (KR) 10-2011-0089956

(51) Int. Cl. H01L 31/075

(52) U.S. Cl. 136/255

(57) ABSTRACT

A thin film solar cell includes a substrate, a first electrode positioned on the substrate, a second electrode separated from the first electrode, and a photoelectric conversion unit positioned between the first electrode and the second electrode. The photoelectric conversion unit includes a p-type semiconductor layer, an intrinsic semiconductor layer, and an n-type semiconductor layer. The p-type semiconductor layer includes a first doped layer, a second doped layer, and a third doped layer. A carbon content of the second doped layer positioned between the first doped layer and the third doped layer is more than a carbon content of the first doped layer and a carbon content of the third doped layer.

This application claims priority to and the benefit of Korean Patent Application No. 10-2011-0089956 filed in the Korean Intellectual Property Office on Sep. 6, 2011, the entire contents of which are incorporated herein by reference.

### BACKGROUND

1. Field of the Disclosure

Embodiments of the invention relate to a thin film solar cell.

2. Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes semiconductor parts, which respectively have different conductive types, for example, a p-type and an n-type, and thus form a p-n junction, and electrodes respectively connected to the semiconductor parts of the different conductive types.

When light is incident on the solar cell, a plurality of electron-hole pairs are produced in the semiconductor parts. The electron-hole pairs are separated into electrons and holes by the photovoltaic effect. The separated electrons move to the n-type semiconductor part, and the separated holes move to the p-type semiconductor part. Then, the electrons and the holes are collected by the electrodes electrically connected to the n-type semiconductor part and the p-type semiconductor part, respectively. The electrodes are connected to each other using electric wires to thereby obtain electric power.

### SUMMARY

Embodiments of the invention provide a thin film solar cell with improved efficiency.

In one aspect, there is a thin film solar cell including a substrate, a first electrode positioned on the substrate, a second electrode separate from the first electrode, and a photoelectric conversion unit positioned between the first electrode and the second electrode, the photoelectric conversion unit including a p-type semiconductor layer, an intrinsic semiconductor layer, and an n-type semiconductor layer, wherein the p-type semiconductor layer includes a first doped layer, a second doped layer, and a third doped layer, wherein a carbon content of the second doped layer positioned between the first doped layer and the third doped layer is more than a carbon content of the first doped layer and a carbon content of the third doped layer.

The carbon content of the second doped layer may be about 3 at % to 15 at %. The carbon content of the first doped layer may be greater than 0 at % and less than about 3 at %. The carbon content of the third doped layer may be greater than 0 at % and less than about 3 at %.

The first doped layer may not contain carbon. The third doped layer may not contain carbon.

An energy band gap of the second doped layer may be greater than an energy band gap of the first doped layer and an energy band gap of the third doped layer. An electrical conductivity of the first doped layer and an electrical conductivity of the third doped layer may be greater than an electrical conductivity of the second doped layer.

The first doped layer, the second doped layer, and the third doped layer may have a mixed crystal structure of amorphous silicon and crystalline silicon. Alternatively, the first doped layer, the second doped layer, and the third doped layer may have a crystal structure of amorphous silicon.

Crystallinity of each of the first doped layer, the second doped layer, and the third doped layer may be about 2% to 50%.

The crystallinity of the first doped layer and the crystallinity of the third doped layer may be greater than the crystallinity of the second doped layer.

A thickness of the second doped layer may be greater than a thickness of the first doped layer and a thickness of the third doped layer.

The thickness of the first doped layer and the thickness of the third doped layer may be about 1 nm to 10 nm, and the thickness of the second doped layer may be about 5 nm to 20 nm.

The intrinsic semiconductor layer may contain amorphous silicon. Alternatively, the intrinsic semiconductor layer may contain crystalline silicon. The intrinsic semiconductor layer is formed of amorphous silicon containing carbon. The intrinsic semiconductor layer is formed of microcrystalline silicon containing carbon.

The thin film solar cell according to the embodiment of the invention includes the p-type semiconductor layer including the three doped layers, in which the carbon content of the middle layer among the three doped layers is more than the carbon content of each of the other two doped layers, thereby improving its efficiency.

### BRIEF DESCRIPTION OF THE DRAWINGS

The accompanying drawings, which are included to provide a further understanding of the disclosure and are incorporated in and constitute a part of this specification, illustrate embodiments of the invention and together with the description serve to explain the principles of the invention. In the drawings:

FIG. 1 illustrates a thin film solar cell according to an exemplary embodiment of the invention;

FIG. 2 illustrates a carbon content of each of doped layers of a p-type semiconductor layer shown in FIG. 1;

FIG. 3 illustrates a double junction solar cell having a pin-pin structure according to an exemplary embodiment of the invention;

FIG. 4 is a table comparing an experimental result of a double junction solar cell according to an embodiment example with an experimental result of a double junction solar cell according to a comparative example;

FIG. 5 illustrates a triple junction solar cell having a pin-pin-pin structure according to an exemplary embodiment of the invention; and

FIG. 6 is a table comparing an experimental result of a triple junction solar cell according to an embodiment example with an experimental result of a triple junction solar cell according to a comparative example.

### DETAILED DESCRIPTION OF THE EMBODIMENTS

Reference will now be made in detail to embodiments of the invention, examples of which are illustrated in the accompanying drawings. This invention may, however, be embodied in many different forms and should not be construed as limited to the embodiments set forth herein. Wherever possible, the same reference numbers may be used throughout the drawings to refer to the same or like parts. It will be understood that detailed description of known arts may be omitted if it is determined that the arts do not aid in the understanding of the embodiments of the invention.

In the drawings, the thickness of layers, films, panels, regions, etc., may be exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on other element, it may be on the entire surface of the other element and may not be on a portion of an edge of the other element.

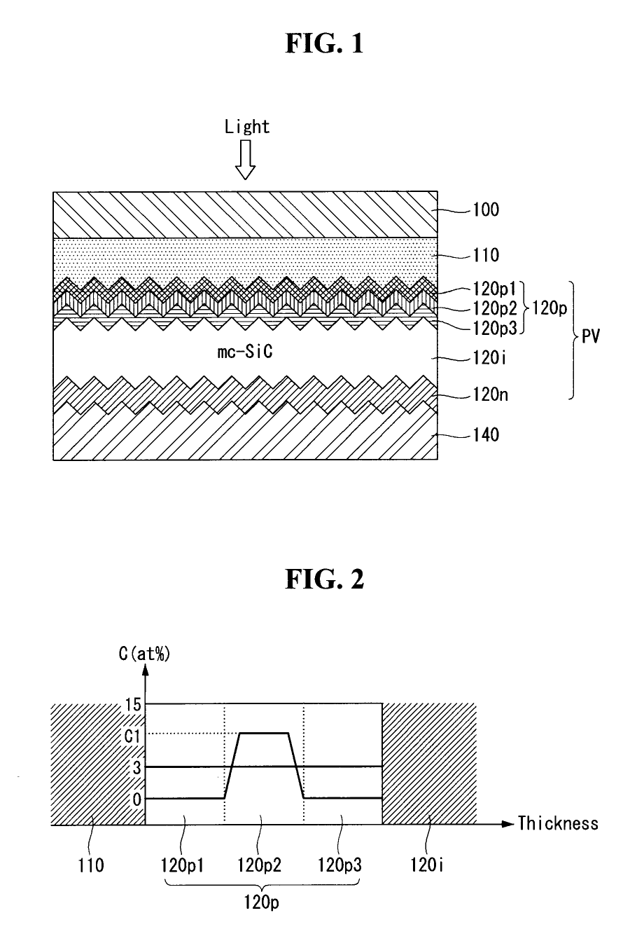

FIG. 1 illustrates a thin film solar cell according to an exemplary embodiment of the invention.

As shown in FIG. 1, a thin film solar cell according to an exemplary embodiment of the invention includes a substrate 100, a first electrode 110, at least one photoelectric conversion unit PV, and a second electrode 140.

The substrate 100 may provide a space for other functional layers. The substrate 100 may be formed of a substantially transparent non-conductive material, for example, glass or plastic, so that light incident on the substrate 100 efficiently reaches the photoelectric conversion unit PV.

The first electrode 110 is positioned under the substrate 100 and contains a conductive material capable of transmitting light so as to increase a transmittance of incident light. For example, the first electrode 110 may contain transparent conductive oxide (TCO). The first electrode 110 may be electrically connected to the photoelectric conversion unit PV. Hence, the first electrode 110 may collect and output carriers (for example, holes) produced by incident light.

A plurality of uneven portions having a pyramid structure may be formed on a lower surface of the first electrode 110. In other words, the first electrode 110 may have a textured surface including the plurality of uneven portions. When the surface of the first electrode 110 is textured, the first electrode 110 may reduce a reflectance of incident light and increase an absorptance of the incident light. Hence, the efficiency of the thin film solar cell may be improved.

The second electrode 140 is separated from the lower surface of the first electrode 110 and is positioned under the photoelectric conversion unit PV. The second electrode 140 may be formed of a metal material with high electrical conductivity so as to increase a recovery efficiency of electric power generated by the photoelectric conversion unit PV. The second electrode 140 may be electrically connected to the photoelectric conversion unit PV and may collect and output carriers (for example, electrons) produced by incident light.

The second electrode 140 may contain at least one of silver (Ag) and aluminum (Al) with high electrical conductivity. The second electrode 140 may have a single-layered structure or a multi-layered structure.

So far, the embodiment of the invention described the structure of the solar cell in which light is incident from the substrate 100. However, in the embodiment of the invention, light may be incident from the second electrode 140 opposite the substrate 100. In this instance, the second electrode 140 is formed of a conductive material capable of transmitting light, and the first electrode 110 is formed of a metal material.

The photoelectric conversion unit PV is positioned between the first electrode 110 and the second electrode 140. The photoelectric conversion unit PV converts light incident on an incident surface of the substrate 100 from the outside into electricity.

The photoelectric conversion unit PV may have a pin structure including a p-type semiconductor layer 120p, an intrinsic (called i-type) semiconductor layer 120i, and an n-type semiconductor layer 120n that are sequentially stacked on the incident surface of the substrate 100 in the order named. Other layers may be included or present in the photoelectric conversion unit PV or therebetween. The p-type semiconductor layer 120p includes a first doped layer 120p1, a second doped layer 120p2, and a third doped layer 120p3.

The pin structure of the photoelectric conversion unit PV, the first doped layer 120p1, the second doped layer 120p2, and the third doped layer 120p3 are described below.

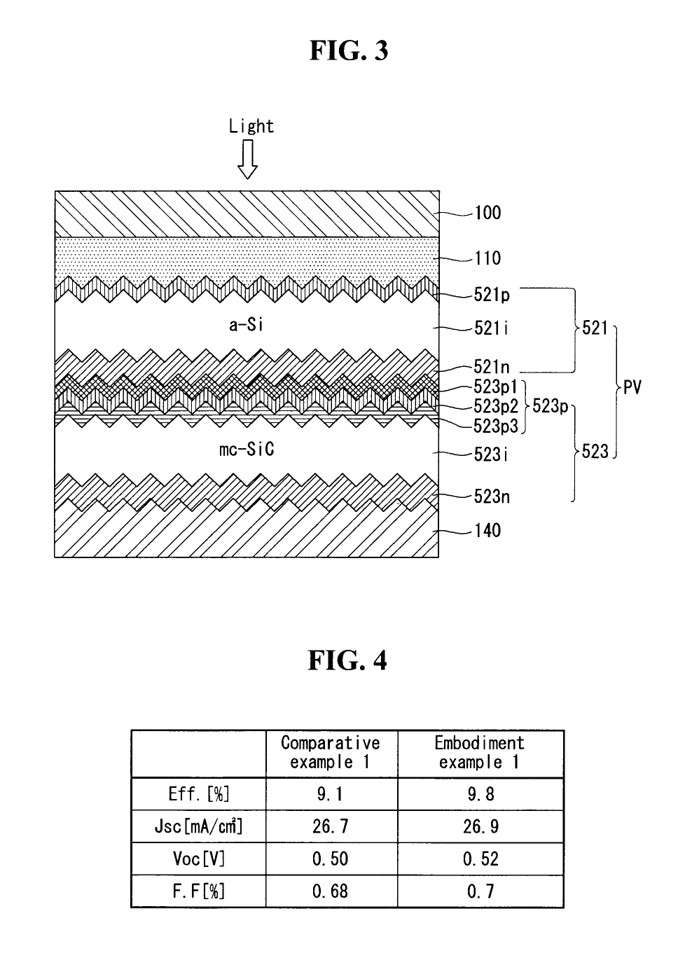

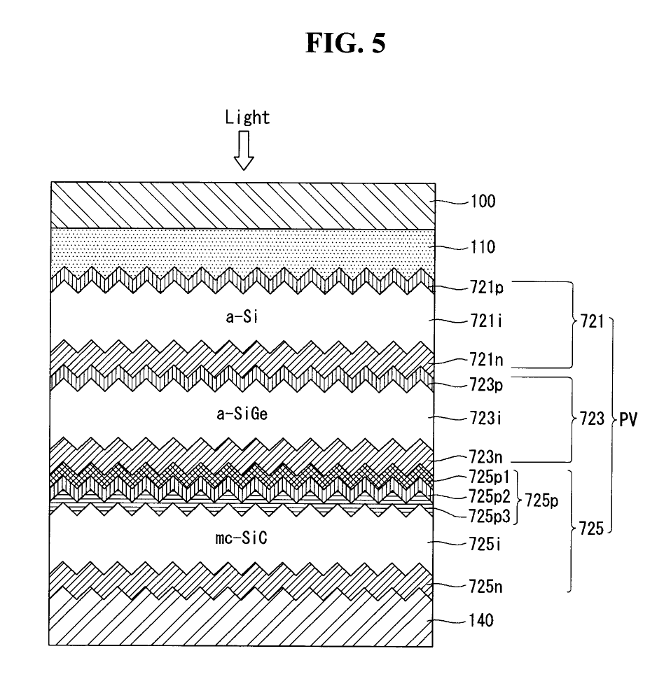

FIG. 1 illustrates the photoelectric conversion unit PV having one pin structure. However, in the embodiment of the invention, the photoelectric conversion unit PV may have two pin structures or three pin structures. The photoelectric conversion unit PV having one pin structure is described as an example with reference to FIG. 1, and the photoelectric conversion unit PV having the plurality of pin structures is described in detail with reference to FIGS. 3 and 5.

More specifically, FIG. 1 illustrates the photoelectric conversion unit PV having the pin structure from the incident surface of the substrate 100. Alternatively, the photoelectric conversion unit PV may have an nip structure from the incident surface of the substrate 100. In the following description, the photoelectric conversion unit PV having the pin structure from the incident surface of the substrate 100 is taken as an example for the sake of brevity.

The p-type semiconductor layer 120p of the photoelectric conversion may be formed using a gas obtained by adding impurities of a first conductive type, for example, impurities of a group III element, such as boron (B), gallium (Ga), and indium (In), to a raw gas containing silicon (Si). In the embodiment of the invention, when the p-type semiconductor layer 120p is doped with the impurities of the group III element, boron (B) generating a minimum defect may be used.

The n-type semiconductor layer 120n may be formed using a gas obtained by adding impurities of a second conductive type opposite the first conductive type, for example, impurities of a group V element, such as phosphorus (P), arsenic (As), and antimony (Sb), to a raw gas containing silicon (Si).

The i-type semiconductor layer 120i is positioned between the p-type semiconductor layer 120p and the n-type semiconductor layer 120n. The i-type semiconductor layer 120i may prevent or reduce a recombination of carriers and may absorb light. The i-type semiconductor layer 120i may absorb incident light to produce carriers such as electrons and holes.

The i-type semiconductor layer 120i may be formed of amorphous silicon containing carbon (C) or crystalline silicon containing carbon (C). For example, as shown in FIG. 1, the i-type semiconductor layer 120i may be formed of microcrystalline silicon (mc-SiC) containing carbon (C).

When the i-type semiconductor layer 120i contains carbon (C), an energy band gap of the i-type semiconductor layer 120i may further increase. Hence, an open-circuit voltage Voc may be improved.

The photoelectric conversion unit PV may be formed using a chemical vapor deposition (CVD) method, such as a plasma enhanced CVD (PECVD) method.

As shown in FIG. 1, doped layers of the photoelectric conversion unit PV, for example, the p-type semiconductor layer 120p and the n-type semiconductor layer 120n may form a p-n junction with the i-type semiconductor layer 120i interposed between the doped layers 120p and 120n.

In such a structure of the photoelectric conversion unit PV, when light is incident on the p-type semiconductor layer 120p, a depletion region is formed inside the i-type semiconductor layer 120i due to the p-type semiconductor layer 120p and the n-type semiconductor layer 120n each having a relatively high doping concentration, thereby generating an electric field. Electrons and holes produced in the i-type semiconductor layer 120i corresponding to a light absorbing layer are separated from each other by a contact potential difference through a photovoltaic effect and move in different directions. For example, the holes may move to the first electrode 110 through the p-type semiconductor layer 120p, and the electrons may move to the second electrode 140 through the n-type semiconductor layer 120n. Hence, the electric power may be produced.

As shown in FIG. 1, the p-type semiconductor layer 120p includes the first doped layer 120p1, the second doped layer 120p2, and the third doped layer 120p3.

The first doped layer 120p1 is positioned closest to the first electrode 110 among the three doped layers of the p-type semiconductor layer 120p, and the second doped layer 120p2 is positioned opposite an incident surface of the first doped layer 120p1. The third doped layer 120p3 is positioned between the second doped layer 120p2 and the i-type semiconductor layer 120i.

The first, second, and third doped layers 120p1, 120p2, and 120p3 may have a crystal structure of amorphous silicon or a mixed crystal structure of amorphous silicon and crystalline silicon. Crystallinity of each of the first, second, and third doped layers 120p1, 120p2, and 120p3 may be about 2% to 50%.

An amount of carbon (C) contained in the second doped layer 120p2 is more than an amount of carbon (C) contained in each of the first doped layer 120p1 and the third doped layer 120p3. Hence, an energy band gap of the second doped layer 120p2 containing more carbon (C) is greater than an energy band gap of the first doped layer 120p1 and an energy band gap of the third doped layer 120p3.

Further, an absorptance of light absorbed in the second doped layer 120p2 containing carbon (C) is less than an absorptance of light obtained when the second doped layer 120p2 does not contain carbon (C). Hence, when the second doped layer 120p2 contains carbon (C), an amount of light absorbed in the i-type semiconductor layer 120i may increase.

As described above, when the second doped layer 120p2 contains more carbon (C) than the other doped layers 120p1 and 120p3, an amount of light absorbed in the p-type semiconductor layer 120p may decrease and a light loss amount may decrease. Hence, the energy band gap may relatively increase, and the open-circuit voltage Voc may further increase. Hence, the efficiency of the solar cell may be improved.

When the thin film solar cell includes both the second doped layer 120p2 containing more carbon (C) and the i-type semiconductor layer 120i formed of carbon-containing amorphous silicon (a-SiC) or carbon-containing microcrystalline silicon (mc-SiC), an absorptance of the i-type semiconductor layer 120i may further increase, and the energy band gap may further increase. Hence, the open-circuit voltage Voc may further increase, and the efficiency of the thin film solar cell may be further improved.

On the other hand, when the p-type semiconductor layer 120p includes only the second doped layer 120p2 containing carbon, it is difficult to improve electrical characteristics of the photoelectric conversion unit PV.

In other words, the energy band gap characteristic of the second doped layer 120p2 containing carbon is excellent, but electrical conductivity of the second doped layer 120p2 containing carbon is low. Hence, it is difficult to improve the electrical characteristics of the photoelectric conversion unit PV.

A reason why the electrical conductivity of the second doped layer 120p2 is low is that a stable crystal structure of the second doped layer 120p2 is converted into an unstable crystal structure because of carbon (C).

To solve the problem of the second doped layer 120p2, the first doped layer 120p1 positioned closest to the first electrode 110 is formed on an incident surface of the second doped layer 120p2, and the third doped layer 120p3 is formed between the second doped layer 120p2 and the i-type semiconductor layer 120i.

Because the carbon content of the first doped layer 120p1 is less than the carbon content of the second doped layer 120p2, electrical conductivity of the first doped layer 120p1 is greater than the electrical conductivity of the second doped layer 120p2. Hence, the first doped layer 120p1 is formed between the first electrode 110 and the second doped layer 120p2, to thereby complement interface junction characteristic between the first electrode 110 and the second doped layer 120p2.

In other words, because the first doped layer 120p1 having the relatively high electrical conductivity is formed between the first electrode 110 and the second doped layer 120p2, a reduction in electrical characteristics of the p-type semiconductor layer 120p resulting from the second doped layer 120p2 may be prevented or reduced.

The third doped layer 120p3 is formed between the second doped layer 120p2 and the i-type semiconductor layer 120i, to thereby complement interface junction characteristic between the second doped layer 120p2 and the i-type semiconductor layer 120i. Further, the third doped layer 120p3 prevents or reduces the degradation of an interface between the second doped layer 120p2 and the i-type semiconductor layer 120i resulting from the diffusion of carbon contained in the second doped layer 120p2.

The function and the operation of each of the doped layers of the p-type semiconductor layer 120p are more efficiently performed when each doped layer has an optimum thickness.

For example, a thickness of the p-type semiconductor layer 120p may be about 7 nm to 40 nm, and a thickness of the second doped layer 120p2 may be greater than a thickness of the first doped layer 120p1 or a thickness of the third doped layer 120p3.

For example, the thickness of the first doped layer 120p1 may be about 1 nm to 10 nm, the thickness of the second doped layer 120p2 may be about 5 nm to 20 nm, and the thickness of the third doped layer 120p3 may be about 1 nm to 10 nm.

As described above, when the thickness of the second doped layer 120p2 is greater than the thickness of the first doped layer 120p1 or the thickness of the third doped layer 120p3, the second doped layer 120p2 may adjust an energy band gap of the photoelectric conversion unit PV. Further, the first doped layer 120p1 or the third doped layer 120p3 may help promote the efficient operation of the second doped layer 120p2.

The carbon content of each doped layer of the p-type semiconductor layer 120p is described in detail below.

FIG. 2 illustrates a carbon content of each of the doped layers of the p-type semiconductor layer 120p shown in FIG. 1.

As shown in FIG. 2, a carbon content Cl of the second doped layer 120p2 is more than a carbon content of the first doped layer 120p1 and a carbon content of the third doped layer 120p3. Alternatively, the first doped layer 120p1 and the third doped layer 120p3 may contain no carbon.

Hence, the energy band gap of the second doped layer 120p2 may be greater than the energy band gap of the first doped layer 120p1 and the energy band gap of the third doped layer 120p3.

As described above, when the energy band gap of the second doped layer 120p2 is greater than the energy band gaps of the first and third doped layers 120p1 and 120p3, an amount of light absorbed in the i-type semiconductor layer 120i increases. Further, the electrical conductivity of the p-type semiconductor layer 120p at an interface between the first electrode 110 and the p-type semiconductor layer 120p is improved. Moreover, interface junction characteristic between the second doped layer 120p2 and the i-type semiconductor layer 120i is complemented, and thus the open-circuit voltage Voc of the photoelectric conversion unit PV is improved. As a result, a fill factor of the solar cell is improved, and photoelectric conversion efficiency of the solar cell is improved.

More specifically, the carbon content C1 of the second doped layer 120p2 may be about 3 at % to 15 at %.

When the carbon content Cl of the second doped layer 120p2 is equal to or more than about 3 at %, a minimum increase width of the open-circuit voltage Voc may be secured. When the carbon content Cl of the second doped layer 120p2 is equal to or less than about 15 at %, an excessive increase in a defect resulting from a large amount of carbon may be prevented. Hence, a reduction in a transfer efficiency of carriers resulting from the defect may be prevented.

FIG. 2 illustrates an example where the first doped layer 120p1 and the third doped layer 120p3 do not contain carbon. However, as described above, the first doped layer 120p1 and the third doped layer 120p3 may contain less carbon than the second doped layer 120p2. For example, the carbon content of each of the first doped layer 120p1 and the third doped layer 120p3 may be more than 0 at % and less than about 3 at %, in consideration of the interface junction characteristic and the electrical conductivity of the first doped layer 120p1 and the third doped layer 120p3.

The thin film solar cell according to the embodiment of the invention includes the p-type semiconductor layer 120p having the three doped layers, in which the middle doped layer of the three doped layers contains more carbon than the other two doped layers, thereby preventing a reduction in the electrical characteristic and the interface junction characteristic and improving the open-circuit voltage Voc of the photoelectric conversion unit PV.

The effect of the p-type semiconductor layer 120p having the three doped layers further increases when the i-type semiconductor layer 120i is formed of carbon-containing microcrystalline silicon (mc-SiC).

So far, the embodiment of the invention described the thin film solar cell including one photoelectric conversion unit. Hereinafter, when the thin film solar cell includes two or three photoelectric conversion units, an operation of the p-type semiconductor layer 120p having the three doped layers is described.

FIG. 3 illustrates a double junction solar cell having a pin-pin structure according to an exemplary embodiment of the invention.

Structures and components identical or equivalent to those described above may be designated with the same reference numerals, and a further description may be briefly made or may be entirely omitted.

As shown in FIG. 3, a photoelectric conversion unit PV of the thin film solar cell according to the embodiment of the invention may include a first photoelectric conversion unit 521 positioned adjacent to the substrate 100 and a second photoelectric conversion unit 523 positioned farther from a substrate 100 than the first photoelectric conversion unit 521.

Each of the first photoelectric conversion unit 521 and the second photoelectric conversion unit 523 may have the pin structure. Thus, a first p-type semiconductor layer 521p, a first i-type semiconductor layer 521i, a first n-type semiconductor layer 521n, a second p-type semiconductor layer 523p, a second i-type semiconductor layer 523i, and a second n-type semiconductor layer 523n may be sequentially stacked on an incident surface of the substrate 100 in the order named. Other layers may be included or present in the first and/or second photoelectric conversion units or therebetween.

The first i-type semiconductor layer 521i may mainly absorb light of a short wavelength band to produce electrons and holes. The second i-type semiconductor layer 523i may mainly absorb light of a long wavelength band to produce electrons and holes.

As described above, because the double junction solar cell absorbs light of the short wavelength band and light of the long wavelength band to produce carriers, the efficiency of the solar cell may be improved.

A thickness of the second i-type semiconductor layer 523i may be greater than a thickness of the first i-type semiconductor layer 521i, so as to sufficiently absorb light of the long wavelength band.

The first i-type semiconductor layer 521i of the first photoelectric conversion unit 521 may contain amorphous silicon (a-Si). The second i-type semiconductor layer 523i of the second photoelectric conversion unit 523 may contain carbon-containing microcrystalline silicon (mc-SiC).

In the double junction solar cell shown in FIG. 3, the first i-type semiconductor layer 521i absorbs light of the short wavelength band to provide the photoelectric effect, and the second i-type semiconductor layer 523i absorbs light of the long wavelength band to provide the photoelectric effect. In this instance, as described above, when the second i-type semiconductor layer 523i contains carbon-containing microcrystalline silicon (mc-SiC), an amount of light of the long wavelength band absorbed in the second i-type semiconductor layer 523i may further increase. As a result, the efficiency of the double junction solar cell may be improved.

In the double junction solar cell shown in FIG. 3, the second p-type semiconductor layer 523p including three doped layers may be formed between the first n-type semiconductor layer 521n and the second i-type semiconductor layer 523i in the same manner as the p-type semiconductor layer 120p shown in FIGS. 1 and 2.

More specifically, a first doped layer 523p1, a second doped layer 523p2, and a third doped layer 523p3 may be sequentially formed on a back surface of the first n-type semiconductor layer 521n positioned relatively close to the first electrode 110 in the order named. A carbon content of the second doped layer 523p2 may be more than a carbon content of the first doped layer 523p1 and a carbon content of the third doped layer 523p3 in the same manner as the p-type semiconductor layer 120p shown in FIGS. 1 and 2. Characteristics of the doped layers 523p1, 523p2, and 523p3 of the second p-type semiconductor layer 523p may be substantially the same as those illustrated in FIGS. 1 and 2.

In the double junction solar cell thus formed, the second p-type semiconductor layer 523p including the three doped layers improves an absorptance of the second i-type semiconductor layer 523i formed of carbon-containing microcrystalline silicon (mc-SiC) and improves the open-circuit voltage Voc of the solar cell. Hence, the photoelectric conversion efficiency of the solar cell may be improved.

FIG. 4 is a table comparing an experimental result of a double junction solar cell including three doped layers with an experimental result of a double junction solar cell including one doped layer.

In FIG. 4, a comparative example 1 indicates an experimental result of a double junction solar cell (having a configuration different from the double junction solar cell shown in FIG. 3) obtained when a second p-type semiconductor layer including one doped layer was formed between a first n-type semiconductor layer 521n and a second i-type semiconductor layer 523i. An embodiment example 1 indicates an experimental result of a double junction solar cell (having the same configuration as the double junction solar cell shown in FIG. 3) obtained when a second p-type semiconductor layer 523p including three doped layers was formed between a first n-type semiconductor layer 521n and a second i-type semiconductor layer 523i.

As shown in FIG. 4, a short circuit current Jsc in the embodiment example 1 was held at a good level similar to a short circuit current Jsc in the comparative example 1. An open-circuit voltage Voc in the embodiment example 1 increased by about 0.02%, compared to an open-circuit voltage Voc in the comparative example 1. A fill factor F.F in the embodiment example 1 increased by about 0.02%, compared to a fill factor F.F in the comparative example 1.

Hence, a photoelectric conversion efficiency Eff in the embodiment example 1 increased by about 0.7%, compared to a photoelectric conversion efficiency Eff in the comparative example 1.

FIG. 5 illustrates a triple junction solar cell having a pin-pin-pin structure according to an exemplary embodiment of the invention.

Structures and components identical or equivalent to those described above may be designated with the same reference numerals, and a further description may be briefly made or may be entirely omitted.

As shown in FIG. 5, a photoelectric conversion unit PV of the triple junction solar cell according to the embodiment of the invention may include a first photoelectric conversion unit 721, a second photoelectric conversion unit 723, and a third photoelectric conversion unit 725 that are sequentially positioned on an incident surface of a substrate 100 in the order named.

More specifically, the first photoelectric conversion unit 721 is positioned adjacent to the substrate 100, the second photoelectric conversion unit 723 is positioned farther from the substrate 100 than the first photoelectric conversion unit 721, and the third photoelectric conversion unit 725 is positioned farther from the substrate 100 than the second photoelectric conversion unit 723.

Each of the first photoelectric conversion unit 721, the second photoelectric conversion unit 723, and the third photoelectric conversion unit 725 may have the pin structure. Thus, a first p-type semiconductor layer 721p, a first i-type semiconductor layer 7211, a first n-type semiconductor layer 721n, a second p-type semiconductor layer 723p, a second i-type semiconductor layer 723i, a second n-type semiconductor layer 723n, a third p-type semiconductor layer 725p, a third i-type semiconductor layer 725i, and a third n-type semiconductor layer 725n may be sequentially positioned on the substrate 100 in the order named. Other layers may be included or present in the first, second, and/or third photoelectric conversion units or therebetween.

The first i-type semiconductor layer 721i, the second i-type semiconductor layer 723i, and the third i-type semiconductor layer 725i may be variously implemented.

As a first example of the configuration illustrated in FIG. 5, the first i-type semiconductor layer 721i and the second i-type semiconductor layer 723i may contain amorphous silicon (a-Si), and the third i-type semiconductor layer 725i may contain microcrystalline silicon (mc-Si).

Further, in the first example, the second i-type semiconductor layer 723i may contain germanium (Ge), and the third i-type semiconductor layer 725i may contain carbon (C).

In this instance, the first i-type semiconductor layer 721i may have a maximum energy band gap among the first, second, and third i-type semiconductor layers, and thus may mainly absorb light of a short wavelength band. The second i-type semiconductor layer 723i may contain germanium-containing amorphous silicon, and thus may have an energy band gap less than the first i-type semiconductor layer 721i. Hence, the second i-type semiconductor layer 723i may absorb light of a middle wavelength band. The third i-type semiconductor layer 725i may contain carbon-containing microcrystalline silicon (mc-SiC) and thus may have a minimum energy band gap less than the second i-type semiconductor layer 723i. Hence, the third i-type semiconductor layer 725i may absorb light of a long wavelength band.

Accordingly, because the triple junction solar cell may efficiently absorb light of a wavelength band wider than the double junction solar cell, the photoelectric conversion efficiency of the triple junction solar cell may be further improved.

A thickness of the third i-type semiconductor layer 725i may be greater than a thickness of the second i-type semiconductor layer 723i, and the thickness of the second i-type semiconductor layer 723i may be greater than a thickness of the first i-type semiconductor layer 721i. The thicknesses of the first, second, and third i-type semiconductor layers 721i, 723i, and 725i may be set so that an absorptance of light of the long wavelength band with respect to the third i-type semiconductor layer 725i further increases.

Accordingly, because the triple junction solar cell shown in FIG. 5 may absorb light of the wavelength band wider than the double junction solar cell, the power production efficiency of the triple junction solar cell may be further improved.

In the triple junction solar cell shown in FIG. 5, the third p-type semiconductor layer 725p including three doped layers may be formed between the second n-type semiconductor layer 723n and the third i-type semiconductor layer 725i in the same manner as the p-type semiconductor layer 120p shown in FIGS. 1 and 2.

More specifically, a first doped layer 725p1, a second doped layer 725p2, and a third doped layer 725p3 may be sequentially formed on a back surface of the second n-type semiconductor layer 723n positioned relatively close to the first electrode 110 in the order named. A carbon content of the second doped layer 725p2 may be more than a carbon content of the first doped layer 725p1 and a carbon content of the third doped layer 725p3 in the same manner as the p-type semiconductor layer 120p shown in FIGS. 1 and 2. Characteristics of the doped layers 725p1, 725p2, and 725p3 of the third p-type semiconductor layer 725p may be substantially the same as those illustrated in FIGS. 1 and 2.

In the triple junction solar cell thus formed, the third p-type semiconductor layer 725p including the three doped layers improves an absorptance of the third i-type semiconductor layer 725i formed of carbon-containing microcrystalline silicon (mc-SiC) and improves the open-circuit voltage Voc of the solar cell. Hence, the photoelectric conversion efficiency of the solar cell may be improved.

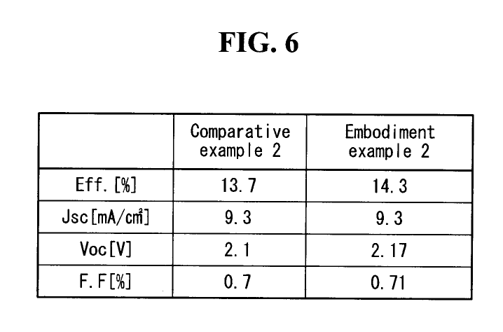

FIG. 6 is a table comparing an experimental result of a triple junction solar cell including three doped layers with an experimental result of a triple junction solar cell including one doped layer.

In FIG. 6, a comparative example 2 indicates an experimental result of a triple junction solar cell (having a configuration different from the triple junction solar cell shown in FIG. 5) obtained when a third p-type semiconductor layer including one doped layer was formed between a second n-type semiconductor layer 723n and a third i-type semiconductor layer 725i. An embodiment example 2 indicates an experimental result of a triple junction solar cell (having the same configuration as the triple junction solar cell shown in FIG. 5) obtained when a third p-type semiconductor layer 723p including three doped layers was formed between a second n-type semiconductor layer 723n and a third i-type semiconductor layer 725i.

As shown in FIG. 6, a short circuit current Jsc in the embodiment example 2 was held at a good level similar to a short circuit current Jsc in the comparative example 2. An open-circuit voltage Voc in the embodiment example 2 increased by about 0.07%, compared to an open-circuit voltage Voc in the comparative example 2. A fill factor F.F in the embodiment example 2 increased by about 0.01%, compared to a fill factor F.F in the comparative example 2.

Hence, a photoelectric conversion efficiency Eff in the embodiment example 2 increased by about 0.6%, compared to a photoelectric conversion efficiency Eff in the comparative example 2.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A thin film solar cell comprising:
a substrate;
a first electrode positioned on the substrate;
a second electrode separated from the first electrode; and
a photoelectric conversion unit positioned between the first electrode and the second electrode, the photoelectric conversion unit including a p-type semiconductor layer, an intrinsic semiconductor layer, and an n-type semiconductor layer,
wherein the p-type semiconductor layer includes a first doped layer, a second doped layer, and a third doped layer,
wherein a carbon content of the second doped layer positioned between the first doped layer and the third doped layer is more than a carbon content of the first doped layer and a carbon content of the third doped layer.

2. The thin film solar cell of claim 1, wherein the carbon content of the second doped layer is about 3 at % to 15 at %.

3. The thin film solar cell of claim 1, wherein the carbon content of the first doped layer is greater than 0 at % and less than about 3 at %.

4. The thin film solar cell of claim 1, wherein the carbon content of the third doped layer is greater than 0 at % and less than about 3 at %.

5. The thin film solar cell of claim 1, wherein the first doped layer does not contain carbon.

6. The thin film solar cell of claim 1, wherein the third doped layer does not contain carbon.

7. The thin film solar cell of claim 1, wherein an energy band gap of the second doped layer is greater than an energy band gap of the first doped layer and an energy band gap of the third doped layer.

8. The thin film solar cell of claim 1, wherein an electrical conductivity of the first doped layer and an electrical conductivity of the third doped layer are greater than an electrical conductivity of the second doped layer.

9. The thin film solar cell of claim 1, wherein the first doped layer, the second doped layer, and the third doped layer each have a mixed crystal structure of amorphous silicon and crystalline silicon.

10. The thin film solar cell of claim 1, wherein the first doped layer, the second doped layer, and the third doped layer each have a crystal structure of amorphous silicon.

11. The thin film solar cell of claim 7, wherein crystallinity of each of the first doped layer, the second doped layer, and the third doped layer is about 2% to 50%.

12. The thin film solar cell of claim 9, wherein the crystallinity of the first doped layer and the crystallinity of the third doped layer are greater than the crystallinity of the second doped layer.

13. The thin film solar cell of claim 1, wherein a thickness of the second doped layer is greater than a thickness of the first doped layer and a thickness of the third doped layer.

14. The thin film solar cell of claim 13, wherein the thickness of the first doped layer and the thickness of the third doped layer are about 1 nm to 10 nm, and the thickness of the second doped layer is about 5 nm to 20 nm.

15. The thin film solar cell of claim 1, wherein the intrinsic semiconductor layer contains amorphous silicon.

16. The thin film solar cell of claim 1, wherein the intrinsic semiconductor layer contains crystalline silicon.

17. The thin film solar cell of claim 1, wherein the intrinsic semiconductor layer is formed of amorphous silicon containing carbon.

18. The thin film solar cell of claim 1, wherein the intrinsic semiconductor layer is formed of microcrystalline silicon containing carbon.

19. The thin film solar cell of claim 1, further comprising at least one other photoelectric conversion unit positioned between the first electrode and the second electrode, wherein the photoelectric conversion unit including the p-type semiconductor layer including the first doped layer, the second doped layer, and the third doped layer is positioned farthest from the substrate than the at least one other photoelectric conversion unit.

20. The thin film solar cell of claim 19, wherein the intrinsic semiconductor layer of the photoelectric conversion unit contains carbon.
